(19) United States
(12) Patent Application Publication
(10) Pub. No.: US 2022/0056868 A1
(43) Pub. Date: Feb. 24, 2022

(54) CONTROL AND CONFIGURATION OF SOFTWARE-DEFINED MACHINES

(71) Applicant: Energy Internet Corporation, Saratoga, CA (US)

(72) Inventors: Shankar Ramamurthy, Saratoga, CA (US); Mohan J. Kumar, Aloha, OR (US)

(21) Appl. No.: 17/519,629

(22) Filed: Nov. 5, 2021

Related U.S. Application Data
(63) Continuation-in-part of application No. 17/072,061, filed on Oct. 16, 2020.
Application No. 17/072,061 is a continuation-in-part of application No. 16/378,243, filed on Apr. 8, 2019, now Pat. No. 10,947,899.
Application No. 16/378,243 is a continuation-in-part of application No. 16/118,886, filed on Aug. 31, 2018, now Pat. No. 10,725,441.
Application No. 16/118,886 is a continuation-in-part of application No. 16/857,854, filed on Apr. 24, 2020.
Application No. 16/857,854 is a continuation-in-part of application No. 16/747,843, filed on Jan. 21, 2020.
Application No. 16/747,843 is a continuation-in-part of application No. 16/378,243, filed on Apr. 8, 2019, now Pat. No. 10,947,899.
(60) Provisional application No. 63/227,499, filed on Jul. 30, 2021.
(60) Provisional application No. 63/178,560, filed on Apr. 23, 2021.
(60) Provisional application No. 63/152,357, filed on Feb. 23, 2021.
(60) Provisional application No. 63/110,417, filed on Nov. 6, 2020.
(60) Provisional application No. 63/048,032, filed on Jul. 3, 2020.
(60) Provisional application No. 63/047,188, filed on Jul. 1, 2020.
(60) Provisional application No. 62/981,629, filed on Feb. 26, 2020.
(60) Provisional application No. 62/916,449, filed on Oct. 17, 2019.
(60) Provisional application No. 62/795,133, filed on Jan. 22, 2019.
(60) Provisional application No. 62/795,140, filed on Jan. 22, 2019.
(60) Provisional application No. 62/784,582, filed on Dec. 24, 2018.
(60) Provisional application No. 62/679,051, filed on Jun. 1, 2018.
(60) Provisional application No. 62/654,718, filed on Apr. 9, 2018.
(60) Provisional application No. 62/654,859, filed on Apr. 9, 2018.
(60) Provisional application No. 62/552,747, filed on Aug. 31, 2017.
(60) Provisional application No. 62/981,629, filed on Feb. 26, 2020.
(60) Provisional application No. 62/916,449, filed on Oct. 17, 2019.
(60) Provisional application No. 62/838,992, filed on Apr. 26, 2019.
(60) Provisional application No. 62/645,859, filed on Mar. 21, 2018.
(60) Provisional application No. 63/246,813, filed on Sep. 22, 2021.

(51) Int. Cl. F02G 1/045; F02G 1/053; G06F 30/323

(52) U.S. Cl. CPC F02G 1/045; F02G 1/053; F02G 2270/90; F02G 2270/70; G06F 30/323

(57) ABSTRACT

Disclosed techniques include control and configuration of software-defined machines. A hardware design for a mechanical system is obtained. The mechanical system includes a plurality of components that includes a liquid piston heat engine. Couplings between the plurality of components are described. A plurality of layers for the mechanical system is defined. The mechanical system that includes the liquid piston heat engine is implemented. The implementation is across the plurality of layers. The implementation is based on the couplings between the plurality of components. The couplings are described using connectivity maps. The implementation is based on construction rules. An application programming interface is used to communicate information on the plurality of layers for the mechanical system. The plurality of layers provides progressive levels of abstraction for the mechanical system.

### RELATED APPLICATIONS

This application claims the benefit of U.S. provisional patent applications “Control of Software Defined Mechanical Machines Using Description Language” Ser. No. 63/110,417, filed Nov. 6, 2020, “Gas Liquefaction Using Hybrid Processing” Ser. No. 63/178,560, filed Apr. 23, 2021, “Energy Storage and Buffering Using Multiple Pressure Containers” Ser. No. 63/152,357, filed Feb. 23, 2021, “Recovery of Work from a Liquefied Gas Using Hybrid Processing” Ser. No. 63/227,499, filed Jul. 30, 2021, and “Hybrid Compressed Air Energy Storage System Using Paired Liquid Pistons” Ser. No. 63/246,813, filed Sep. 22, 2021.

This application is also a continuation-in-part of U.S. patent application “Desalination Using Pressure Vessels” Ser. No. 17/072,061, filed Oct. 16, 2020, which claims the benefit of U.S. provisional patent applications “Desalination Using Pressure Vessels” Ser. No. 62/916,449, filed Oct. 17, 2019, “Controlled Liquefaction and Energy Management” Ser. No. 62/981,629, filed Feb. 26, 2020, “Energy Transfer Using High-Pressure Vessel” Ser. No. 63/047,188, filed Jul. 1, 2020, and “Controlled Liquefaction Using Compatible Materials for Energy Management” Ser. No. 63/048,032, filed Jul. 3, 2020.

The U.S. patent application “Desalination Using Pressure Vessels” Ser. No. 17/072,061, filed Oct. 16, 2020, is also a continuation-in-part of U.S. patent application “Energy Storage and Management Using Pumping” Ser. No. 16/378,243 , filed Apr. 8, 2019, which claims the benefit of U.S. provisional patent applications “Modularized Energy Management Using Pooling” Ser. No. 62/654,718, filed Apr. 9, 2018, “Energy Storage and Management Using Pumping” Ser. No. 62/654,859, filed Apr. 9, 2018, “Power Management Across Point of Source to Point of Load” Ser. No. 62/679,051, filed Jun. 1, 2018, “Energy Management Using Pressure Amplification” Ser. No. 62/784,582, filed Dec. 24, 2018, “Energy Management Using a Converged Infrastructure” Ser. No. 62/795,140, filed Jan. 22, 2019, and “Energy Management Using Electronic Flywheel” Ser. No. 62/795,133, filed Jan. 22, 2019.

The U.S. patent application “Energy Storage and Management Using Pumping” Ser. No. 16/378,243, filed Apr. 8, 2019, is also a continuation-in-part of U.S. patent application “Energy Management with Multiple Pressurized Storage Elements” Ser. No. 16/118,886, filed Aug. 31, 2018, which claims the benefit of U.S. provisional patent applications “Energy Management with Multiple Pressurized Storage Elements” Ser. No. 62/552,747, filed Aug. 31, 2017, “Modularized Energy Management Using Pooling” Ser. No. 62/654,718, filed Apr. 9, 2018, “Energy Storage and Management Using Pumping” Ser. No. 62/654,859, filed Apr. 9, 2018, and “Power Management Across Point of Source to Point of Load” Ser. No. 62/679,051, filed Jun. 1, 2018.

This application is also a continuation-in-part of U.S. patent application “Energy Transfer Through Fluid Flows” Ser. No. 16/857,854, filed Apr. 24, 2020, which claims the benefit of U.S. provisional patent applications “Energy Transfer Through Fluid Flows” Ser. No. 62/838,992, filed Apr. 26, 2019, “Desalination Using Pressure Vessels” Ser. No. 62/916,449, filed Oct. 17, 2019, and “Controlled Liquefaction and Energy Management” Ser. No. 62/981,629, filed Feb. 26, 2020.

The U.S. patent application “Energy Transfer Through Fluid Flows” Ser. No. 16/857,854, filed Apr. 24, 2020, is also a continuation-in-part of U.S. patent application “Energy Management Using a Converged Infrastructure” Ser. No. 16/747,843, filed Jan. 21, 2020, which claims the benefit of U.S. provisional patent applications “Energy Management Using a Converged Infrastructure” Ser. No. 62/795,140, filed Jan. 22, 2019, “Energy Management Using Electronic Flywheel” Ser. No. 62/795,133, filed Jan. 22, 2019, “Energy Transfer Through Fluid Flows” Ser. No. 62/838,992, filed Apr. 26, 2019, and “Desalination Using Pressure Vessels” Ser. No. 62/916,449, filed Oct. 17, 2019.

The U.S. patent application “Energy Management Using a Converged Infrastructure” Ser. No. 16/747,843, filed Jan. 21, 2020 is also a continuation-in-part of U.S. patent application “Energy Storage and Management Using Pumping” Ser. No. 16/378,243, filed Apr. 8, 2019, which claims the benefit of U.S. provisional patent applications “Modularized Energy Management Using Pooling” Ser. No. 62/654,718, filed Apr. 9, 2018, “Energy Storage and Management Using Pumping” Ser. No. 62/654,859, filed Apr. 9, 2018, “Power Management Across Point of Source to Point of Load” Ser. No. 62/679,051, filed Jun. 1, 2018, “Energy Management Using Pressure Amplification” Ser. No. 62/784,582, filed Dec. 24, 2018, “Energy Management Using a Converged Infrastructure” Ser. No. 62/795,140, filed Jan. 22, 2019, and “Energy Management Using Electronic Flywheel” Ser. No. 62/795,133, filed Jan. 22, 2019.

The U.S. patent application “Energy Storage and Management Using Pumping” Ser. No. 16/378,243, filed Apr. 8, 2019, is also a continuation-in-part of U.S. patent application “Energy Management with Multiple Pressurized Storage Elements” Ser. No. 16/118,886, filed Aug. 31, 2018, which claims the benefit of U.S. provisional patent applications “Energy Management with Multiple Pressurized Storage Elements” Ser. No. 62/552,747, filed Aug. 31, 2017, “Modularized Energy Management Using Pooling” Ser. No. 62/654,718, filed Apr. 9, 2018, “Energy Storage and Management Using Pumping” Ser. No. 62/654,859, filed Apr. 9, 2018, and “Power Management Across Point of Source to Point of Load” Ser. No. 62/679,051, filed Jun. 1, 2018.

Each of the foregoing applications is hereby incorporated by reference in its entirety.

### FIELD OF ART

This application relates generally to hardware control and more particularly to control and configuration of software-defined machines.

### BACKGROUND

Since the earliest days of recorded history, humankind has used machines to improve life and make survival easier. From simple tools to help with agricultural tasks to more complex machines like ramps and wheels, machines have been an integral part of human existence. Over time, many scientific discoveries have led to more and more sophisticated machines to assist humankind. The industrial revolution marked an important inflection in the endemic nature of machines helping in society. More recently, computing machines have been used to perform many tasks heretofore unrealizable without computer assistance. Modern computers are more flexible than their precursors which were unique, dedicated hardware machines built to perform only one or a few predetermined purposes. One area that has benefitted from machines is the production and storage of energy.

Around the world, the demand for energy is increasing, driven by population growth and economic development. Energy is used for light, heat, transportation, and powering machines, among other applications. Many projections predict world-wide energy use will grow 50% by 2050. Oil, natural gas, and coal have long been energy staples, but they are non-renewable, carbon-emitting sources. There is a need for energy solutions that are clean, affordable, reliable, sustainable, secure, efficient, safe, and more. Renewable energy solutions like solar and wind offer safe, clean energy options, but they can be intermittent, unreliable sources. Electricity must be available 24 hours a day. Even small fluctuations in supply can cause disruptions that cost billions of dollars. The electricity grid is a complex system that balances power supply and demand for predictable human activity and during unexpected changes like overloads and storms. Energy storage can stabilize the power grid and supplement intermittent sources by providing backup power, leveling loads, and managing energy resources. Energy storage means energy is captured when excess is available and it is retained until a later time where there is a need because demand exceeds supply. Energy is available in multiple forms including electrical, kinetic, chemical, latent heat, radiation, and more. However, not all forms of energy are easily storable. Often energy storage requires converting energy from one form into another that can be safely and economically stored. Some techniques provide short-term storage, and others can provide longer-term storage. Some provide small-scale storage, and others can provide large-scale storage.

A variety of energy storage techniques are used today. Batteries are a common form of energy storage. They are used in small applications like powering flashlights and cell phones. They can also be used in larger applications like electric vehicles. Others are used in larger applications, like storing electricity from wind and solar farms. Flywheels store electrical energy as rotational energy in a spinning mass. Hydroelectric dams store energy using two reservoirs of water at different elevations. When energy supply exceeds demand, often at night, water is pumped into the upper reservoir. Then when electricity is needed, the water is released into the lower reservoir by flowing downhill through turbines that generate electricity. Hydrogen can store energy to be used in fuel cells and engines or turbines to generate electricity. Thermal storage concentrates solar plants to capture heat from the sun and store the energy in fluids or salts, which can be later used to generate electricity. Thus energy storage can be used to help meet ever increasing energy demands, and machines can play an important role in energy storage.

### SUMMARY

As worldwide energy usage continues to grow, so do energy needs. The need for a reliable and resilient energy supply, as well as the need for grid modernization, is increasing. Access to diverse and secure energy sources is critical. Clean and inexpensive energy is desired, not just in urban areas, but also in remote locations where micro-grid solutions can be favorable. Energy storage and generation provides a solution to these energy needs. Storage and generation technology provides backup power, levels loads, and offers energy management, which can strengthen and stabilize the power grid. However, industrial design and architecture of energy storage and generation systems are labor intensive, iterative, and turnkey. Programmatic control is targeted to a specific implementation and cannot easily adapt to a different set of circumstances or operations. Any change to the control system requires further software development and system validation. This limits the scalability, extensibility, and adaptability of the control system.

Disclosed techniques include control and configuration of software-defined machines. A hardware design for a mechanical system is obtained. The mechanical system includes a plurality of components that includes a liquid piston heat engine. Couplings between the plurality of components are described. A plurality of layers for the mechanical system is defined. The mechanical system that includes the liquid piston heat engine is implemented. The implementation is across the plurality of layers. The implementation is based on the couplings between the plurality of components. The couplings are described using connectivity maps. The implementation is based on construction rules. An application programming interface (API) is used to communicate information on the plurality of layers for the mechanical system. The plurality of layers provides progressive levels of abstraction for the mechanical system.

A computer-implemented method for hardware control is disclosed comprising: obtaining a hardware design for a mechanical system comprising a plurality of components that comprises a liquid piston heat engine; describing couplings between the plurality of components; defining a plurality of layers for the mechanical system; and implementing the mechanical system that comprises the liquid piston heat engine across the plurality of layers based on the couplings between the plurality of components. The couplings are described using connectivity maps. The implementing of the mechanical system is based on construction rules. The mechanical system implements a reverse osmosis desalination system.

An application programming interface (API) is used to communicate information on the plurality of layers for the mechanical system. The plurality of layers provides progressive levels of abstraction for the mechanical system.

Describing the couplings and defining the plurality of layers are accomplished using a hardware description language. The hardware description language comprises an algebraic description of operational control and configuration. The hardware description language provides for self-learning management of the mechanical system. The hardware description language is used within a machine learning context. An application programming interface (API) is used to communicate information on the plurality of layers for the mechanical system. The system that comprises the liquid piston heat engine is implemented across the plurality of layers based on the couplings between the plurality of components. The implementing comprises outputting a file including a hardware description language, which describes a software-defined machine.

Various features, aspects, and advantages of various embodiments will become more apparent from the following further description.

### BRIEF DESCRIPTION OF THE DRAWINGS

The following detailed description of certain embodiments may be understood by reference to the following figures wherein:

FIG. 1 is a flow diagram for control and configuration of software-defined machines.

FIG. 2 is a flow diagram for application programming interface (API) usage.

FIG. 3 is a block diagram for energy management.

FIG. 4 illustrates an energy internet block diagram.

FIG. 5 shows a software-defined liquid piston heat engine (LPHE).

FIG. 6 illustrates a desalination system with brine recovery.

FIG. 7 shows a software-defined machine (SDM) application programming interface.

FIG. 8A illustrates a liquid piston heat engine (LPHE) to pressurize a liquid.

FIG. 8B illustrates a logical model of a liquid piston heat engine.

FIG. 9 shows example power distribution.

FIG. 10 is a system diagram for control and configuration of software-defined machines.

### DETAILED DESCRIPTION

This disclosure provides techniques for control and configuration of software-defined machines. A description language such as a hardware description language is used for control of software-defined machines. The machines can be mechanical in nature, or they can comprise non-mechanical elements, such as in an electrical machine. The hardware machines can be based on a liquid piston heat engine which can be used for energy storage, recovery, and generation. Many energy generation techniques are widely used to meet the daily energy demands large and small of individuals, households, small businesses, farms, manufacturing facilities, laboratories, governments, and so on. Traditional energy generation techniques have been based on burning fossil fuels, tapping natural resources such as hydro or geothermal sources, and so on. As energy usage has continued to expand, and energy consumers have continued to demand energy from alternative and renewable sources, energy generation has also expanded to use techniques based on solar, wind, wave action, tidal action, biofuels, biogas, and so on. Perhaps the principal obstacle to wider adoption of these and other renewable sources of energy is the intermittent nature of the sources. Windless days and nighttime hours affect energy generation based on wind and solar sources, respectively.

Energy with intermittent availability or energy in excess of present load requirements can be captured. The captured energy can be stored or cached when the energy is being produced, and can be extracted and used at a later time for energy generation to meet an energy shortfall. A similar strategy can be used based on price, where energy is stored when production cost is low, then later extracted when the energy production cost is high. The stored energy can be used in combination with other energy sources such as grid power or microgrid (local) power to meet energy demands at given times of high demand. Storage can include a period of time, where the period of time can be a short-term basis or a long-term basis. Regardless of energy conversion technique, energy losses are introduced when energy is converted from one energy type to another energy type. Further losses occur when storing energy, extracting energy, generating energy, routing energy, etc. Minimizing the energy losses is critical to any energy storage and retrieval/recovery technique. Electrical energy storage is possible based on mature technologies such as sealed lead acid storage battery technologies, but the high costs of the immense battery banks required for such storage are prohibitive in terms of up-front investment and maintenance expenses. Further, batteries are problematic for long-term storage purposes because of charge leakage.

A liquid piston heat engine can be used with other components including pressure vessels, valves, turbines, and/or pumps, for energy storage and recovery. High-pressure vessels can be used to compress a gas within the vessel by pumping a liquid into the high-pressure vessel. Various types of liquids can be used to accomplish the compression. The liquids can include water, a specialized fluid such as FreonTM, liquid air, liquid nitrogen, and so on. The compressed gas can be stored in a tank, an underwater bladder, unused oil infrastructure, and the like. The compressed gas can be stored in a storage reservoir such as an underground cavern or an aquifer. The compressed gas can be stored for a time basis such as a short-term basis or a long-term basis. When the energy represented by the stored compressed gas is needed to meet scheduled energy demands, to meet energy shortfalls, etc., then the compressed gas can be extracted from the storage reservoir. However, the pressure at which the gas is stored can be too high to directly operate a piece of equipment such as a turbine. The gas that is extracted from the storage reservoir can be directed to a second high-pressure vessel. Similar to the first high-pressure vessel, the second high-pressure vessel can contain a gas that can be used to accomplish a gas pressure within the second high-pressure vessel. The fluid within the second high-pressure vessel can be used to spin the turbine to generate energy such as electrical energy.

Energy such as generated electrical energy can be stored as a compressed gas, a pressurized liquid, and so on. The stored energy within the compressed gas can be later extracted by directly or indirectly spinning a turbine. The energy storage and extraction are most efficient when the pressurizing the gas is substantially isothermal. Substantially isothermal pressurizing or depressurizing of the gas can be accomplished by spraying a liquid into the high-pressure vessel. The injected liquid can be heated or cooled using heat exchangers to maintain substantially isothermal operation. The energy that is stored can be received from a wide diversity and disparity of energy sources. Energy can be stored when the amount of energy available from the points of generation exceeds the energy demand at the time of energy generation. The energy can be stored for a period of time. The energy storage can include gas-based energy storage using high-pressure vessels. The energy storage can include electrical energy storage using batteries or capacitors. The stored energy can be provided after a period of time to meet energy demands of current loads, dynamic loads, seasonal loads, and the like. Gas pressurized using high-pressure vessels can be stored in storage reservoirs for time bases including short-term and long-term bases. The storage and the extraction of the energy can be controlled by a processor-based energy management system. The processor-based energy management system can be implemented based on a software-defined machine. Managing the obtaining, connecting, providing, and delivering of energy is a complex and highly challenging task. Energy management can be influenced by many factors such as seasonal factors including the weather, variable energy generation pricing schemes, wildly varying energy demand, and so on. Energy management can be further complicated by an expanding energy customer base, quickly changing customer energy demands, requirements of service level agreements (SLAs), energy policies, etc. Despite the growing use of renewable energy resources such as solar, wind, wave action, tidal, geothermal, biogas, and the like, two significant challenges remain: the amount of energy produced by a given renewable energy source is highly variable, and the availability of the renewable energy source is inconsistent. As an example, wind energy is only available when wind is present, solar energy only when the sun is shining, wave action energy only when there is wave action, and so on.

Other disclosed techniques include control and configuration of software-defined machines. The control of a software-defined machines can include the configuring or the configuration involved in machine definition. The description language can include a general purpose language or a hardware description language. A software-defined machine can be used for energy management. Energy can be obtained locally from a microgrid or farther afield using a grid. The energy can be derived from conventionally generated sources, renewable sources, etc., and can be stored. The stored energy can be used for energy generation at a later time. The energy can be generated using fuels such as coal, natural gas, or nuclear sources; using hydro power or geothermal energy; using renewable sources such as solar, wind, tidal, wave-action, bio-fuels or biogas; using pump-turbine sources such as compressed air, steam, or ice; using backup power sources such as diesel-generator (DG) sets; and so on. Access to a fluid-based local energy transfer distribution network is obtained. The energy transfer distribution can be based on one or more fluids, where the fluids can include water, liquid air, a specialty liquid such as Freon™, etc. The fluid-based local energy transfer distribution network can include at least two heterogeneous fluids. The energy transfer within the local energy transfer distribution network can be accomplished using multiple phases. The fluid-based local energy transfer distribution network can include a homogeneous fluid in liquid and gaseous phases.

A hardware design is obtained for a mechanical system comprising a plurality of components that comprises a liquid piston heat engine. The hardware design can include power generation capacities, power load requirements, storage requirements, seasonal adjustments, and so on. The liquid piston heat engine can use a high-pressure gas to pressurize a liquid, a high-pressure liquid to compress a gas, and so on. The compressing the gas can accomplish liquefaction of the gas. The components can include pressure vessels, valves, turbines, or pumps. The mechanical system can be based on energy storage and generation assemblies. The energy storage and generation assemblies can include a pump-turbine and a pressure vessel. At least one of the one or more fluid-based energy storage and generation assemblies can include a pump running at an optimum performance-pressure point. The liquid piston heat engine-based energy storage and generation assemblies can be parts of a larger energy management system that can include a large-scale energy storage subsystem. The large-scale energy storage subsystem can store electrical energy, potential energy, thermal energy, kinetic energy, chemical energy, etc. A hardware design is obtained for a mechanical system comprising a plurality of components that comprises a liquid piston heat engine. Couplings are described between the plurality of components. A plurality of layers is defined for the mechanical system. The mechanical system is implemented that comprises the liquid piston heat engine across the plurality of layers, based on the couplings between the plurality of components.

Fluid-based energy from the energy storage and generation assemblies is delivered to the fluid-based local energy transfer distribution network. The delivering is based on an energy control management system executing on one or more processors. The delivering can include providing local fluid-based services, where the local fluid-based services supply local consumer applications. The consumer application can include a water nozzle, an air nozzle, a water Venturi function, an air Venturi function, a vacuum supply, space heating, a fluid-based rotation, space cooling, hot water, or cold water. The energy control management system uses supply profiles and demand profiles to adjust the delivering. The energy control management system provides valve control information to the one or more fluid-based energy storage and generation assemblies. The obtaining, the connecting, the providing, and the delivering comprise an energy internet converged infrastructure.

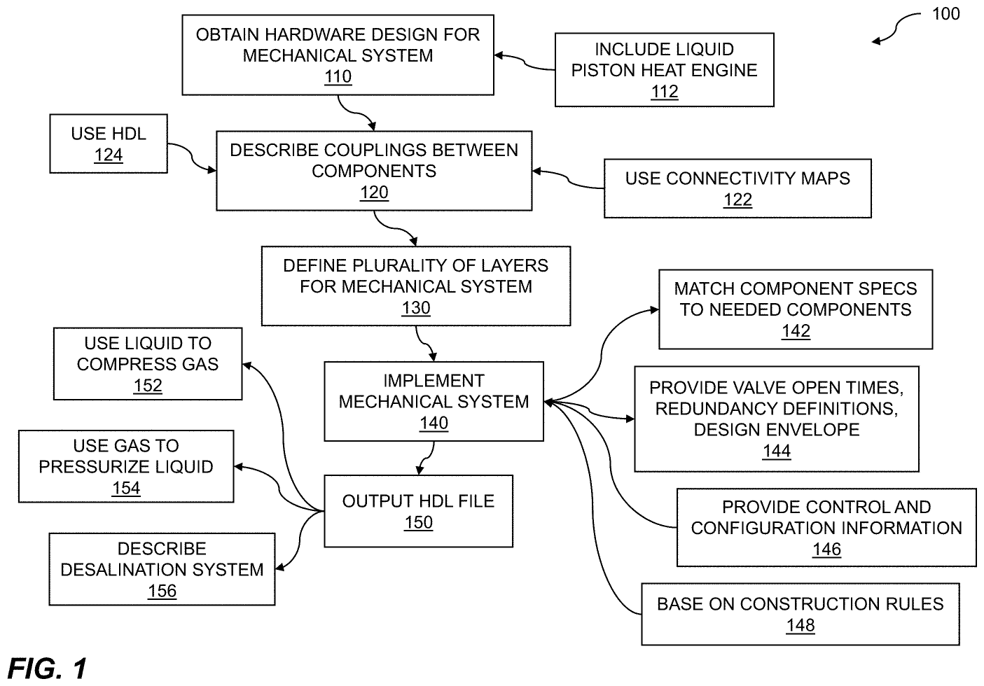

FIG. 1 is a flow diagram for control and configuration of software-defined machines. The software-defined mechanical machines can include machines for energy storage, generation, and management. The energy storage, generation, and management can be based on one or more assemblies, where the one or more assemblies can include fluid-based energy storage and generation assemblies. The fluid-based energy storage and generation assemblies can include a liquid piston heat engine (LPHE). The fluid-based energy storage and generation assembly can include multiple pressure vessels, parallel pipes to accommodate fluid expansion or compression, etc. The fluid can include water, liquid air, liquid nitrogen, and the like. The fluid can be used to compress a gas such as air or nitrogen, a specialty gas such as FreonTM, and so on. The fluid can be used to move a liquid, such as by using the fluid to spin a pump-turbine. The pump-turbine can be used to move the liquid to create hydraulic head. The fluid in which energy is stored can be used to generate energy. The fluid can be used to spin a turbine, the pump-turbine, and the like. The fluid-based energy can include hot air, liquid air, cold air, or vacuum services. The fluid-based energy storage and generation assemblies can be parts of a large energy storage and generation subsystem. The energy storage and generation subsystem can include further assemblies for storing energy in other forms. The further energy storage and generation subsystems can include multiple batteries or capacitors, pressurized storage elements such as high-pressure water, pressurized air, steam, ice-water slurry, and the like.

A hardware design is obtained for a mechanical system 110. The mechanical system includes a plurality of components that comprises a liquid piston heat engine (LPHE). An LPHE can operate using a gas such as air and one or more liquid pistons. The liquid pistons can replace mechanical pistons. The gas and the liquid can be chosen to minimize diffusion between the gas and the liquid in the piston. The gas can be used to pressurize the liquid, and the liquid can be used to compress the gas. Couplings are described between the plurality of components. The couplings can include pipes for fluids or gases, wires for electrical charge, valves or smart valves, and so on. A plurality of layers is defined for the mechanical system. The layers can include layers of abstraction, where the layers of abstraction can include low level, detailed layers of abstraction, layers that can describe modules or assemblies, high levels of abstraction that can describe the function of the mechanical system, and the like. The mechanical system is implemented that comprises the liquid piston heat engine across the plurality of layers based on the couplings between the plurality of components. The implementing the mechanical system can include outputting a file of code based on a hardware description language. The hardware description language enables a user to describe one or more desired functions of the machine using algebraic or Boolean expressions. As a result, the implementation of the mechanical machine can be quickly and easily modified simply by changing the code. The implementing includes matching needed component specifications with available components. The available components can include components that have not been allocated to another machine, components not offline for maintenance or repair, etc. The implementing can include detailed operational information. The implementing includes providing valve open times, redundancy definitions, or design envelope parameters. The design envelope parameters can be based on power generation capacity, a maximum desalination capability, and the like.

A flow 100 for control of software-defined mechanical machines using a description language is shown. The description language, such as a hardware description language can control the machine by configuring the machine, operating the machine, monitoring the machine, adjusting or modifying the machine, and so on. The machine can be based on a liquid piston heat engine (LPHE). The LPHE can be used for energy management including energy generation, storage, and distribution. Energy, such as electrical energy obtained from a traditional electrical grid, energy from renewable sources, locally generated energy, gas or diesel generated electrical energy, and so on, can be stored and used for energy generation. Other forms of energy including thermal energy, mechanical energy, kinetic energy, pressure, etc. can be stored. The energy can be transformed into an energy format which can be stored for a length of time, where the length of time can include a short-term basis, a long-term basis, etc. Energy management can be based on one or more energy control policies, energy production costs, service level agreements, energy needs, and the like. An energy management policy can be used for storing, retrieving, generating, or extracting energy from an energy storage assembly. The energy storage assembly can be a large-scale energy storage assembly or can be a small-scale energy storage assembly.

The flow 100 includes obtaining a hardware design for a mechanical system comprising a plurality of components. The mechanical system can include a software-defined energy system for distributing energy. In embodiments, the mechanical system includes energy storage. The storage can include energy storage on a short-term basis, energy storage on a long-term basis, and the like. In other embodiments, the mechanical system further includes energy generation. The hardware design can be based on design criteria such as machine functions, capabilities, operating constraints, cost constraints, redundancy requirements, and the like. In embodiments, the hardware design comprises a plurality of constraints for the mechanical system or components. The constraints can include power generation, storage, recovery, and transmission constraints; cost constraints; power policy or service level agreement constraints; and the like. In other embodiments, the hardware design comprises a plurality of goals for the mechanical system. The goals can include reliability goals, redundancy goals, etc.

In the flow 100, the mechanical system comprises a liquid piston heat engine 112. In embodiments, the liquid piston heat engine can include a water piston heat engine (WPHE). The liquid piston heat engine can use fluid-based energy transfer. Fluid-based energy transfer distribution can use one or more fluids or one or more phases (e.g., liquid, gas) for energy transfer. While fluid-based energy storage and generation techniques are discussed, energy storage further can be based on battery storage, capacitor storage, inductive storage, compressed air storage, steam or ice storage, ice-water slurry, and so on. Storage can include the use of chemical, methane, or some other type of storage. Discussed below, energy storage and generation assemblies can be formed by coupling components together. The assemblies can include a pump-turbine and pressure vessel assembly. The pressure vessel can include energy storage elements such as high-pressure chambers, compression-expansion chambers, compressed air chambers, and so on. The pressure vessels can be located above ground, located below ground, submerged in water, etc. The pressure vessels can include unused oil infrastructure such as unused or non-productive oil well infrastructure, unused salt caverns, aquifers, large cavities underground, or porous rock structures capable of holding air or water under pressure. The storage elements of an energy storage and generation assembly can store various types of energy including electrical energy, thermal energy, kinetic energy, mechanical energy, hydraulic energy, and so on.

The flow 100 includes describing couplings 120 between the plurality of components. The components can include one or more of pump-turbines, pressure vessels, input energy sources, latent energy sources, energy losses, energy storage, and the like. The couplings can include valves, smart valves, pipes, wires, power panels, cooling interfaces, and the like. The components can include controller components, sensors, telemetry components, etc. The couplings can be described using connectivity maps 122. The connectivity maps can include information on components and their interconnections, or how they are connected. The connectivity maps can include graphical representations, tabular representations, digital representations, abstracted representations, and the like.

In the flow 100, the describing the couplings and the defining the plurality of layers (discussed below) is accomplished using a hardware description language 124. The hardware description language can be based on a general-purpose language such as C, C++, Python, etc. The hardware description language can include a language that defines capabilities, functions, component descriptions, etc., that support the description of the mechanical machine. In embodiments, the hardware description language can include an algebraic description of control operations. The algebraic description can include arithmetic operators, exponentials, roots, and so on. The hardware description language can include integro-differential expressions for describing control operations. In other embodiments, the hardware description language can further include a Boolean set of control operators. The Boolean set of operations can include AND, OR, NAND, NOR, XOR, NOT, and so on. In embodiments, the hardware description language can provide for programmatic management of the mechanical system. The mechanical system can be described using the hardware description language, controlled by the language, etc. In other embodiments, the hardware description language can provide for self-learning management of the mechanical system. Artificial intelligence (AI) techniques such as self-learning techniques can be applied to the machine design. In embodiments, the hardware description language can be used within a machine learning context. The machine learning can “learn” about the operation of the machine as the machine is used to perform tasks such as energy generation, storage, recovery, distribution, and so on. The machine learning can be used to improve the machine to better meet its design objectives.

The flow 100 includes defining a plurality of layers 130 for the mechanical system. The plurality of layers can include components such as couplings, submodules and modules, subassemblies and assemblies, and the like. The plurality of layers can be described using software, where the software includes code, instructions, functions, routines, etc. In embodiments, an application programming interface (API) can be used to communicate information on the plurality of layers for the mechanical system. The API simplifies descriptions of interactions between the layers. In embodiments, the plurality of layers can provide progressive levels of abstraction for the mechanical system. The abstraction layers can include low-level abstraction layers, high-level abstraction layers, and so on. A low-level abstraction layer can describe components and couplings; a mid-level abstraction layer can describe modules and assemblies; and a high-level abstraction layer can describe machine function, usage policies, etc. In embodiments, the plurality of layers can aggregate further components at higher levels of abstraction. These further components can include the modules, assemblies, and so on discussed previously and throughout. The API can be used to communicate control information. In embodiments, the API communicates information on the duration or schedule of energy generation or storage.

The flow 100 includes implementing the mechanical system 140 that comprises the liquid piston heat engine across the plurality of layers based on the couplings between the plurality of components. Since the mechanical system that is being implemented is software-defined, the implementation can be based on code, instructions, function or routine calls, and the like. In the flow 100, the implementing includes matching needed component specifications 142 with available components. The matching specifications can include matching electrical charge storage with available batteries and capacitors; matching pressure requirements with available pressure vessels; matching generation requirements with available pump-turbines or diesel-generator (DG) sets, and the like. In the flow 100, the implementing includes providing valve open times, redundancy definitions, or a design envelope 144. The valve open times can be based on units of time such as seconds, minutes, hours, and so on. The redundancy definitions can include a component redundancy number or a tolerable fails number. The redundancy definitions can include 1N+1 redundancy, 2N redundancy, and the like. In embodiments, the design envelope can include a maximum power generation capability or a maximum desalination capability. The design envelope can comprise design envelope parameters.

The implementing the mechanical system 140 can include providing control and configuration information 146. The control and configuration information enables the components to properly operate together for the intended system functionality. The same couplings, layers, and components can implement a different function with different control and configuration information, thus highlighting the software definition of the machine. The implementing the mechanical system 140 can be based on construction rules 148. The construction rules can describe various “legal” combinations of components, component use conditions, component reliability limitations, component connections and interconnections, and so on. The construction rules can be accessed by using a lookup table, using a graphical editor, using machine-learned constructs, etc. The construction rules can be edited for various different industries, companies, countries, and so on.

In the flow 100, the implementing includes outputting a file 150 including a hardware description language (HDL). The HDL can be based on a general-purpose language such as C, C++, or Python, a language tuned to describing hardware such as a mechanical machine, and the like. The HDL can be used as is to configure, operate, monitor, control, etc., the software-defined machine. The HDL can be compiled, assembled, linked, etc., for use with the software-defined machine. In embodiments, the hardware description language can describe a software-defined machine (SDM). The SDM can be based on the variety of components described above such as valves, pipes, pressure vessels, pump-turbines, etc. In the flow 100, the software-defined machine can describe utilizing a liquid 152 to compress a gas. The liquid can comprise a liquid piston, where the liquid piston can be used to compress the gas. The liquid of the liquid piston and the gas can be chosen to minimize diffusion at the interface between the liquid piston and the gas. In embodiments, liquefaction can be accomplished for a gas within the liquid piston heat engine. In the flow 100, the software-defined machine describes utilizing a gas 154 to pressurize a liquid. Instead of pumping the liquid to compress the gas, the gas can be pumped to pressurize the liquid. The pressurized liquid can be used to spin a turbine to generate energy such as electrical energy. In the flow 100, the software-defined machine can describe a reverse osmosis desalination system 156.

Various steps in the flow 100 may be changed in order, repeated, omitted, or the like without departing from the disclosed concepts. Various embodiments of the flow 100 can be included in a computer program product embodied in a non-transitory computer readable medium that includes code executable by one or more processors.

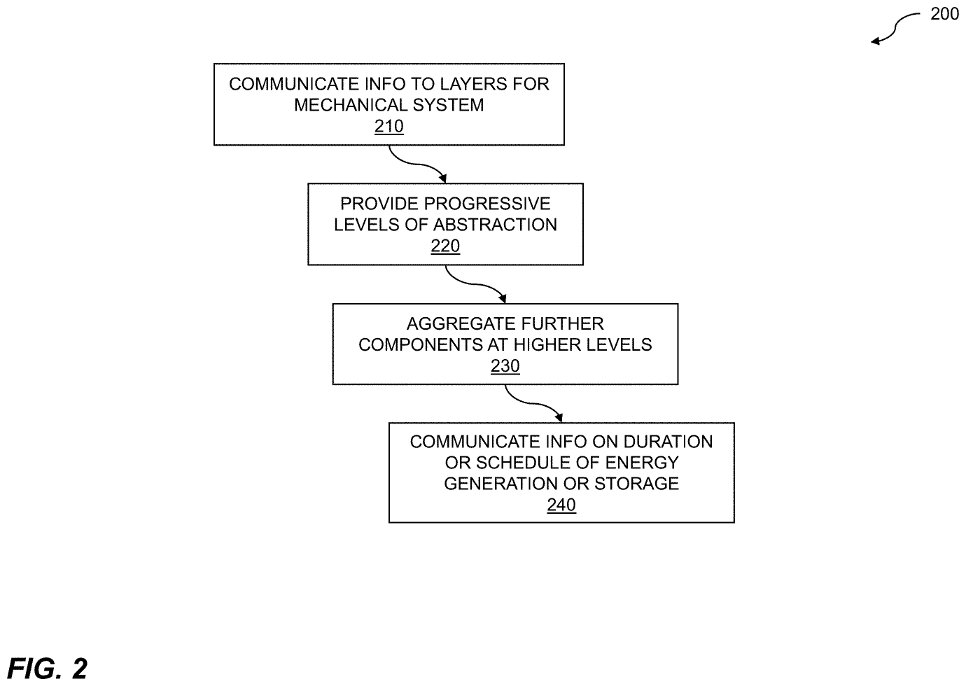

FIG. 2 is a flow diagram for application programming interface (API) usage. Discussed throughout, an application programming interface can be used to communicate information and data associated with couplings, layers, and components within the software-defined mechanical system to software associated with specifying, designing, and/or managing the system. The API can simplify coding of the software-defined machine, enable third party applications to access the software-defined machine, and so on. The API can simplify and standardize access to functions, instructions, and so on that can control and monitor the software-defined machine. The API enables control of software-defined mechanical machines using a description language. A hardware design is obtained for a mechanical system comprising a plurality of components that comprises a liquid piston heat engine. Couplings are described between the plurality of components. A plurality of layers is defined for the mechanical system. The mechanical system is implemented that comprises the liquid piston heat engine across the plurality of layers based on the couplings between the plurality of components.

The flow 200 includes communicating information 210 on the plurality of layers for the mechanical system. The information that can be communicated can include power load requirements, power availability, an inventory of and status of the plurality of components, information on the couplings between and among the components, and so on. The information can include telemetry information from one or more sensors associated with the components. The information can further include power policy information, service level agreement information, and the like. In the flow 200, the plurality of layers provides progressive levels of abstraction 220 for the mechanical system. The levels of abstraction can vary from a low level at which details about a component can be included, to a high level at which the software-defined mechanical machine can be described by its function. In a usage example, consider levels of abstraction associated with a vehicle. A low level of abstraction can include a parts list comprising formed sheet steel, plastic components, bolts, wire, and so on. Although the parts may be recognizable to an observer as parts associated with a vehicle, there is no information about how the parts are assembled, torques applied to the bolts, locations of the formed steel plates, what functions the parts serve, etc. At a high level of abstraction, the function of the vehicle can be described. The vehicle can start, accelerate, decelerate, turn, stop, and so on. While the high level of abstraction describes the function of the vehicle, the high level “hides” the low-level components list. Applying the usage example to a software-defined machine, the low level of abstraction can include a list of components associated with a liquid piston heat engine, valves, smart valves, couplings, etc. The high level of abstraction can include choosing a source to power a pump-turbine through a valve for a period of time.

In the flow 200, the plurality of layers aggregates further components 230 at higher levels of abstraction. The layers of abstraction can list components to be used for a software-defined machine (low level), the couplings between components (increasing level), the forming of submodules or modules from the components (increasing level), the forming of subassemblies or assemblies from the modules (increasing level), and so on to describing functions, operations, controls, etc. of the software-defined machine (high level). The aggregating further components at higher levels of abstraction is accomplished using the hardware description language. In embodiments, the hardware description language can include an algebraic description of control operations. An algebraic description can be based on an elementary equation of free variables. In embodiments, the hardware description language can include an integro-differential description, a discrete description, and so on. Other descriptions such as logical descriptions can be used. In embodiments, the hardware description language further includes a Boolean set of control operators. The Boolean set of control operators can be based on logical AND, OR, NOR, XOR, NOT, and the like.

In the flow 200, the API communicates information on duration or schedule of energy generation or storage 240. Recall that energy management objectives can include configuring power sources and other components to provide power, determining a power load requirement over time, matching power sources to power loads, providing additional power when power loads exceed power supply, storing excess power, recovering stored power, maintaining components, meeting service level agreements, enacting power policies, and so on. In order to meet these objections, information regarding power generation requirements, energy storage levels, and so on, are required. Further, the amount of power that can be generated can be based on the capabilities of the generation components and the amount of stored energy available to enable the generation. The information on duration or schedule of energy generation or storage can include electrical charge in batteries or capacitors; an amount of a compressed gas in a pressure vessel, and amount of pressurized liquid in a pressure vessel, capacity of a pump-turbine, an amount of stored liquid air, etc. The schedule can include using stored energy, holding stored energy, replenishing stored energy, etc. The duration can include an amount of time determined based on the amounts of stored energy remaining.

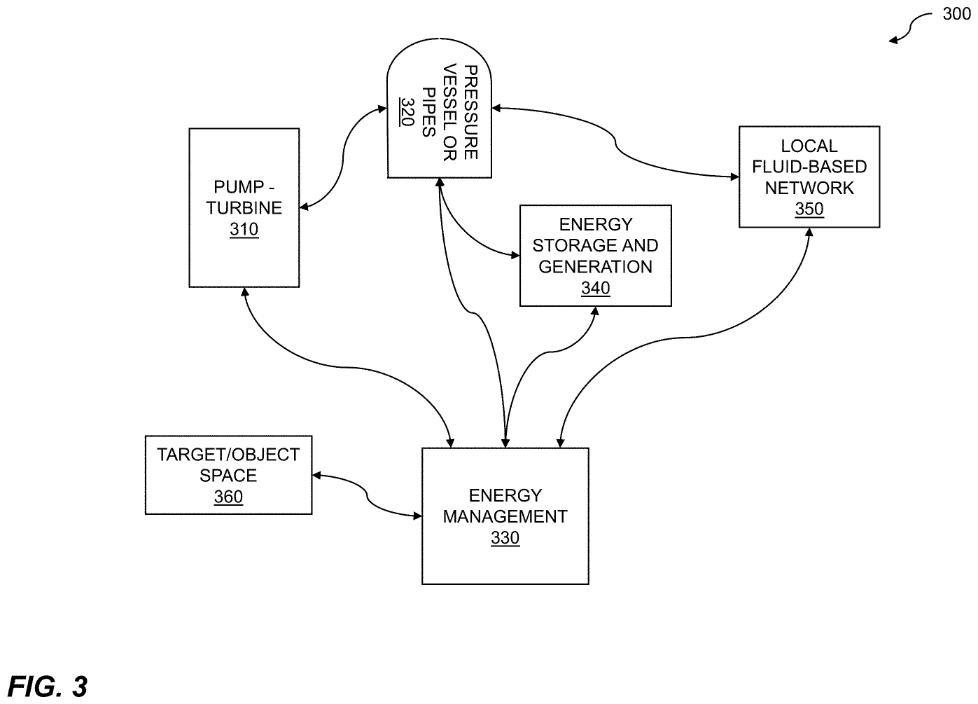

FIG. 3 is a block diagram for energy management. Energy management can be based on control and configuration of software-defined machines. The software-defined machines can describe utilizing a liquid to compress a gas, utilizing a gas to pressurize a liquid, and so on. The machines can include a converged infrastructure, where the converged infrastructure can include fluid-based assemblies for energy storage and generation. The fluid-based assemblies can include assemblies that use the compressed gas or the pressurized liquid. A hardware design is obtained for a mechanical system comprising a plurality of components that comprises a liquid piston heat engine. Couplings are described between the plurality of components. A plurality of layers is described for the mechanical system. The mechanical system is implemented that comprises the liquid piston heat engine across the plurality of layers based on the couplings between the plurality of components. The implementing is based on a hardware description executing on one or more processors.

Energy management 300 can include a pump-turbine 310. In embodiments, the pump-turbine can comprise separate pump and turbine components, a combined pump-turbine component, etc. The pump-turbine can be coupled to a vessel. The vessel can comprise a pressure vessel or pressure pipes 320. Energy management can include more than one pump-turbine/pressure vessel or pressure pipes assembly. The pressure vessel can include an air compression tank, a cavern, unused oil infrastructure, and so on. The pressure pipes can include pressure amplification pipes.

The pump-turbine/pressure vessel or pipes assembly can be connected to an energy management component 330. The energy management component can include an energy control management system, where the energy control management system can include software that can be executed on one or more processors. The energy management component can be coupled to energy storage and generation 340. Various types of energy, such as electrical energy, chemical energy, thermal energy, kinetic energy, potential energy, etc., can be stored. Energy storage such as electrical energy storage can include batteries, capacitors, and so on. Fluid-based energy storage and generation assemblies can include multiple parallel pipes to accommodate fluid expansion or compression. The energy management can control the pump of the pump-turbine. In embodiments, at least one of the one or more fluid-based energy storage and generation assemblies includes a pump running at an optimum performance-pressure point. Other energy storage techniques can be used. When the energy being stored is electrical energy, the electrical energy can be converted between direct current (DC) electrical energy and alternating current (AC) electrical energy. Energy storage can be accomplished using flywheels which can be separate from or included as part of a motor or generator.

The energy management can include a local fluid-based network 350. The fluid-based network can include energy management, energy storage and generation, pressure vessels or pressure pipes, pump-turbines, and so on. The local fluid-based network can be used for delivering fluid-based energy. In embodiments, the delivering includes providing local, fluid-based services. The fluid-based services can include domestic services, industrial or manufacturing services, and the like. In embodiments, the local, consumer applications can include a water nozzle, an air nozzle, a water Venturi function, an air Venturi function, a vacuum supply, space heating, a fluid-based rotation, space cooling, hot water, or cold water. The delivering can provide other services such as motion services. In embodiments, the delivering includes providing a fluid-based equivalent mechanical range of motion through fluid transfer. The energy management can include a target/object space 360.

Fluid-based energy transfer can include conveying a fluid flow to a target object or target space. The conveyance of the fluid flow can be accomplished using ducts, pipes, Venturi functions, nozzles, and so on. In embodiments, the conveyance can include two-phase heterogeneous or two-phase homogeneous compression. A pump or pump-turbine can be used to pressurize water for example, where the pressurized water can be used to compress air or other gas. The pump or pump-turbine can be used to compress air or a gas, where the pressurized air or gas can be used to pressurize a liquid such as water.

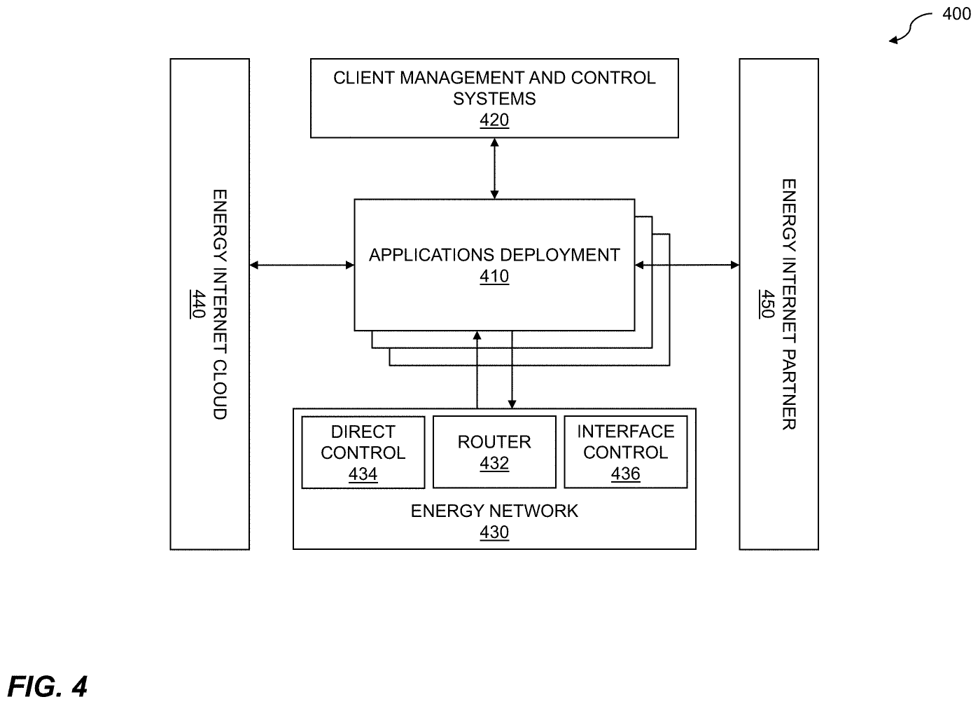

FIG. 4 illustrates an energy internet block diagram. An energy internet 400 enables energy management, where the energy management can be accomplished using control and configuration of software-defined machines. Energy management is further based on energy transfer through fluid flows, where the fluids can include compressed, liquefied gases, pressurized liquids, and so on. A hardware design is obtained for a mechanical system comprising a plurality of components that comprises a liquid piston heat engine. Couplings are described between the plurality of components. A plurality of layers is defined for the mechanical system. The mechanical system is implemented that comprises the liquid piston heat engine across the plurality of layers based on the couplings between the plurality of components. The implementing is based on a software-defined mechanical machine system executing on one or more processors. The energy internet can include applications deployment 410. The applications deployment for an energy internet can include a cluster, where the cluster includes one or more application programming interfaces (APIs) for handling data, policies, communications, control, and so on. The data can include energy storage, pump-turbine storage, energy from waterpower, grid energy, etc. The data can include information from energy generators, partners, and so on. The data can further include third-party data from parties including energy consumers such as oil rigs; solar, wind, tidal, or wave-action farms; data centers; and the like.

Applications deployment can communicate with client management and control systems 420. The management can include infrastructure management, microgrid management, operating management, automated controls, and so on. The management can include management of client legacy equipment. The communicating of applications deployment with client management and control systems can include collecting data from one or more points of energy generation, one or more points of energy load, etc. The communicating can further include sending one or more energy control policies. The energy control policies can be based on the energy, energy information, energy metadata, availability of a large-scale energy storage subsystem, and the like. The energy internet can include an energy network 430. The energy network can include one or more energy routers 432, direct control 434, interface control 436, and so on. An energy router 432 can include digital switches for routing energy from a point of energy generation to a point of energy load. An energy router can be coupled to one or more direct control 434 sensors for detecting switch status, point of source status, point of load status, etc. An energy router can be coupled to direct control actuators for steering energy from one or more points of source to a given point of load. An energy router can be further connected to one or more third-party interface control 436 sensors and third-party interface control actuators. The interface control sensors and interface control actuators can be coupled to equipment such as legacy equipment which may not be directly controllable.

The energy internet (EI) can include an energy internet cloud 440. The energy internet cloud can include an energy internet ecosystem, an energy internet catalog, and so on. The energy internet cloud can include an energy internet secure application programming interface (API) through which the EI cloud can be accessed. The EI ecosystem can include third-party applications such as an application or app store, app development and test techniques, collaboration, assistance, security, and so on. The EI cloud can include an EI catalog. The EI catalog can include technology models, plant and equipment information, sensor and actuator data, operation patterns, etc. The EI cloud can include tools or “as a service” applications such as learning and training, simulation, remote operation, and the like. The energy internet can include energy internet partners 450. The EI partners can provide a variety of support techniques including remote management, cloud support, cloud applications, learning, and so on.

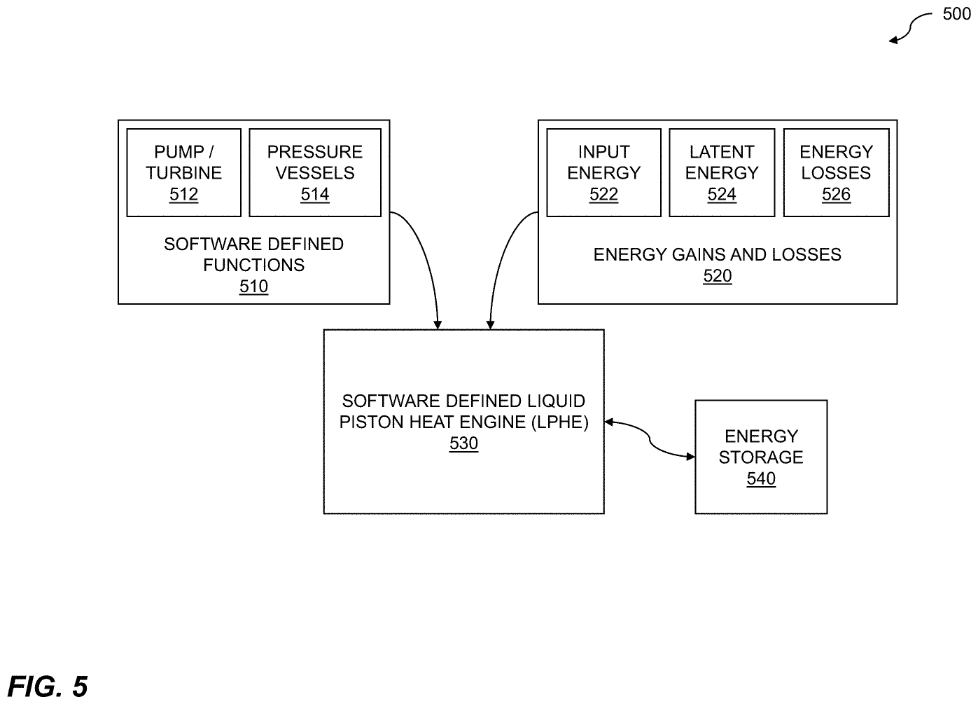

FIG. 5 shows a software-defined liquid piston heat engine. Energy can be generated, stored, recovered, transformed, delivered, and so on, to meet energy load requirements. At times, the energy load requirements can be dynamic. Energy storage can be performed when a surfeit of energy is being generated from energy sources including renewable energy sources such as wind, solar, tidal, wave-action, and so on. The energy can be stored on a short-term basis, such as a length of time substantially less than one week, or on a long-term basis, such as a length of time substantially more than one day. The energy transforming and delivering can be based on control and configuration of software-defined machines. A hardware design is obtained for a mechanical system comprising a plurality of components that comprises a liquid piston heat engine. Couplings are described between the plurality of components. A plurality of layers is defined for the mechanical system. The mechanical system is implemented that comprises the liquid piston heat engine across the plurality of layers based on the couplings between the plurality of components. In embodiments, the delivering includes providing local, fluid-based services, where the local, fluid-based services supply local consumer applications. The local consumer applications include a water nozzle, an air nozzle, a water Venturi function, an air Venturi function, a vacuum supply, space heating, a fluid-based rotation, space cooling, hot water, or cold water.

A software-defined liquid piston heat engine system 500 is shown. The liquid piston heat engine includes one or more software-defined functions 510. The one or more software-defined functions can configure or control energy management system components, subsystem components, etc. The software-defined functions can include a pump-turbine function 512. The pump-turbine function can be used to control components such as one or more pumps, one or more turbines, and so on. The pump-turbine function can include one or more pump-turbine subsystems. Embodiments include operating the pump-turbine subsystem at an optimal pressure-performance point for the pump-turbine subsystem. An optimum pressure-performance point can be determined using one or more processors. The pump-turbine function can comprise physical components, moving components, etc. The software-defined functions can include one or more pressure vessels 514. The one or more pressure vessels can be used to store energy within a pressurized fluid, a pressurized gas, and the like. The one or more pressure vessels can include above-ground tanks, below-ground tanks, caverns such as salt caverns, unused oil infrastructure such as unused oil wells, etc.

The liquid piston heat engine can include energy gains and losses 520. Energy gains can include input energy 522. The input energy can include energy that can be input for storage. The input energy can include grid energy, locally generated energy, renewable energy, and so on. Energy gains can include latent energy 524. Latent energy can be captured from phase changes such as a change from a gas to a liquid, from a liquid to a solid, and so on. The latent energy can be stored. The liquid piston heat engine can include energy losses. Energy losses 526 can include pressure losses from pressurized vessels, temperature losses, electrical charge leakage, and so on. The system 500 includes a software-defined liquid piston heat engine (LPHE) 530. The software-defined LPHE can use software to configure the software-defined functions, to control energy storage and recovery, and so on. The LPHE can include an energy management system that can be operated by an energy management control system. The energy management control system can add or remove energy generation subsystems or energy storage subsystems as needed. The energy management control system can support hot swapping of one or more subsystems. Hot swapping subsystems can include replacing faulty subsystems, swapping out subsystems for maintenance, and the like. In embodiments, the energy management control system can control coupling of the energy, the pump-turbine subsystem, and the one or more pressure amplification pipes. The energy management control system, such as the fluid-based energy management system, includes storing energy for a period of time. The period of time can include a short-term basis or a long-term basis. In embodiments, the short-term basis can be an integer number of seconds, minutes, hours, or days, wherein the integer number of seconds, minutes, hours, or days comprises a length of time substantially less than one week. Other time increments can be used. In other embodiments, the long-term basis can be an integer number of weeks, months, seasons, or years, wherein the integer number of weeks, months, seasons, or years comprises a length of time substantially more than one day.

The system 500 includes energy storage 540. Energy that can be stored can includes electrical energy, chemical energy, mechanical energy, fluid energy, gas energy, and so on. Energy can be stored using one or more of the energy storage and generation assemblies. In embodiments, energy storage and generation assemblies comprise multiple, parallel pipes to accommodate fluid expansion or compression. As discussed throughout, the pipes, including the parallel pipes, can include a high-pressure input pipe, a hierarchy of intermediate pressure pipe layers, low pressure storage pipes, and so on. In embodiments, the fluid of the one or more fluid-based energy storage and generation assemblies can include liquid air. Further liquids may also be used within the energy storage and generation assemblies. In other embodiments, the further liquids can include liquid nitrogen, Freon™, and the like. The LPHE liquid can comprise water, such as fresh water, sea water, polluted water, wastewater, brine, and so on.

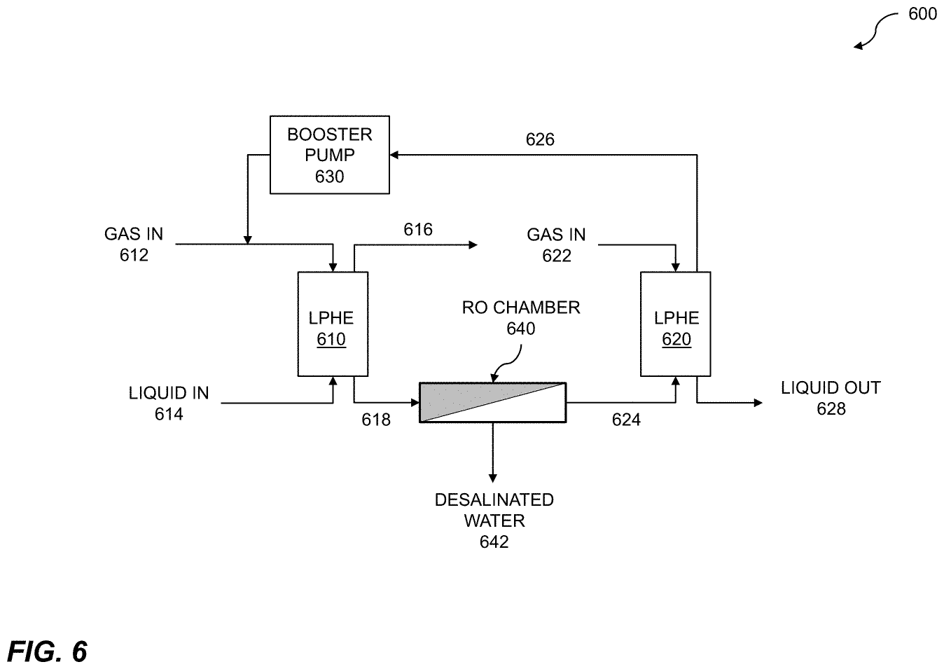

FIG. 6 illustrates a desalination system with brine recovery 600. The desalination system can be implemented using control and configuration of software-defined machines. A hardware design is obtained for a mechanical system comprising a plurality of components that comprises a liquid piston heat engine. Couplings are described between the plurality of components. A plurality of layers is defined for the mechanical system. The mechanical system is implemented that comprises the liquid piston heat engine across the plurality of layers based on the couplings between the plurality of components. The implementing is based on a software-defined mechanical machine system executing on one or more processors.

The illustrative system 600 includes a liquid piston heat engine 610. The liquid piston heat engine LPHE enables transfer of work between gases and liquids with no mechanically moving parts. A Liquid In 614, such as sea water, is allowed to enter and fill LPHE 610 by appropriately opening and closing valves (not shown) on input and output lines to a first LPHE 610 (and a second LPHE 620, described later). Gas In 612, which is environmental air or other type of air, is pressurized to a high pressure, such as a pressure of 200 atmospheres, and it is allowed to enter LPHE 610 to pressurize the entrapped liquid, or in this case, sea water. The pressurized sea water 618 is then allowed to enter a reverse osmosis chamber 640, where the pressure will enable desalinated water 642 to exit chamber 640 and be used for any suitable fresh water application. In addition, brine 624 also exits the chamber 640. The brine 624 is “saltier” sea water, because fresh water has been extracted by the reverse osmosis of chamber 640. After some or all of the usable pressure contained in LPHE 610 is expended by moving pressurized sea water 618 through chamber 640, additional Liquid In 614 can be allowed to enter LPHE 610 as largely depressurized gas 616 is allowed to exit. Another pressurizing cycle can then commence.

Because the brine 624 leaving the chamber 640 has not been completely depressurized to ambient (atmospheric) pressure, work can be further recovered by allowing the brine to pressurize a gas within a second liquid piston heat engine 620. The gas in LPHE 620 is sourced from Gas In 622 and can also be environmental air. Alternatively, Gas In 622 can be sourced from the largely depressurized gas 616 of LPHE 610. In either case, brine 624 pressurizes the gas contained in LPHE 610, which is delivered as compressed gas 626 to booster pump 630, which can further compress the gas 626 until it achieves the same or similar pressure as Gas In 612, thus performing a brine work recovery function. Finally, the leftover brine within LPHE 620 is forced or allowed to drain out as Liquid Out 628, which can be introduced back into the source for Liquid In 614 (e.g., the ocean).

It should be noted that LPHE 610 and LPHE 620 can be operated in synchronization to provide efficient software-defined machine operation. It should be further noted that a LPHE operating in a compression mode can be cooled by a cooling liquid (e.g., water) internal spray to enable substantially isothermal operation. Likewise, a LPHE operating in an expansion mode can be heated by a warming liquid internal spray to enable substantially isothermal operation.

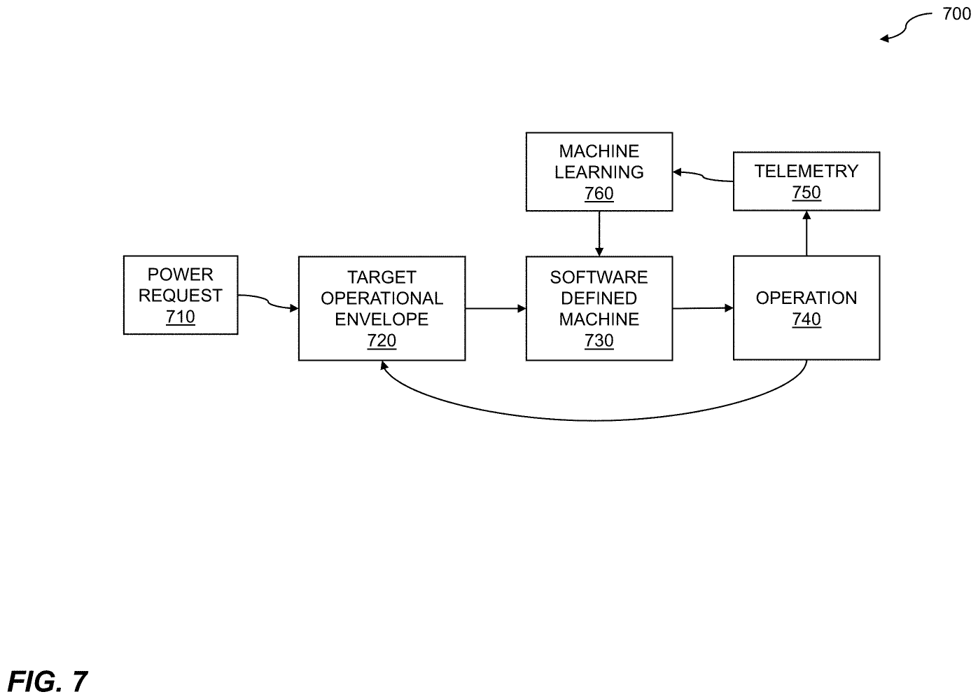

FIG. 7 shows a software-defined machine (SDM) application programming interface. Discussed throughout, a software-defined machine or SDM can be controlled using a description language. The description language can include a high-level language such as a general-purpose language, a hardware description language designed for energy management, and so on. To provide access to the description language, an application programming interface or API can be provided. The API simplifies coding of the configuration and control of the SDM by providing commands, functions, routines, and so on, that can be coded directly or can be called from an application such as a third-party application. The SDM API enables control of a software-defined mechanical machine using a description language. A hardware design is obtained for a mechanical system comprising a plurality of components that comprises a liquid piston heat engine. Couplings are described between the plurality of components. A plurality of layers is defined for the mechanical system. The mechanical system is implemented that comprises the liquid piston heat engine across the plurality of layers based on the couplings between the plurality of components.

A software-defined machine application programming interface is shown 700. A power request 710 is received. The power request can be based on current power requirements, anticipated or peak requirements, contractual power requirements, and so on. The power request can be used to develop a target operational envelope 720. In order to attain the target operational envelope, a design envelope can be proposed. The design envelope can be used to design software-defined power generation systems, software-defined desalination systems, and so on. In embodiments, the design envelope can include a maximum power generation capability or a maximum desalination capability. The design envelope can be used to propose a software-defined machine 730. The proposed software-defined machine can be based on components, couplings between components, and so on. The components can include a liquid piston heat engine. The operation 740 of the proposed software-defined machine can be put into “operation”. In the context of developing the software-defined machine, the operation of the proposed design can be based on one or more simulations. The operating characteristics of the software-defined machine, whether in operation or being simulated, can be measured based on telemetry 750. The telemetry can be used to measure power provided, power needed, operations of the software-defined machine such as valve opening and closing, an amount of time that a valve is open or closed, pressure within a pressure vessel (PV), and so. The data collected by the telemetry can be provided for machine learning 760. The machine learning can be used to “tune” or optimize the software-defined machine 730. In embodiments, the hardware description language can provide for self-learning management of the mechanical system. The self-learning management can be used to adapt the software-defined machine for faster response to power load needs, more efficient use of components, and the like. In other embodiments, the hardware description language can be used within a machine learning context. The machine learning context can include deep learning. The operation 740 can be used to update the target operational envelope. The various steps can be repeated in part or in whole to improve the software-defined machine.

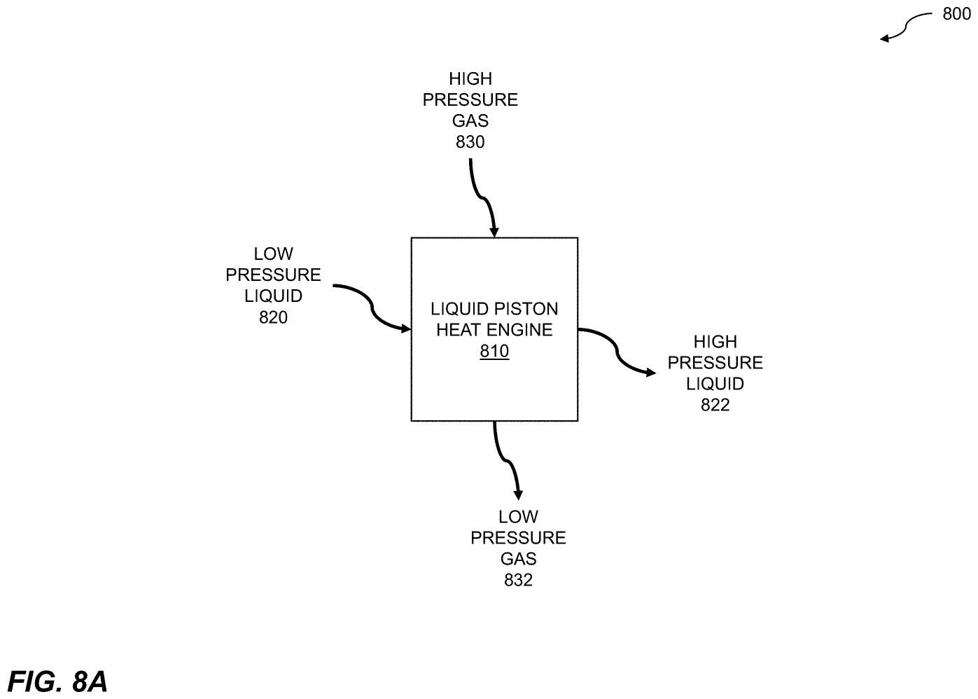

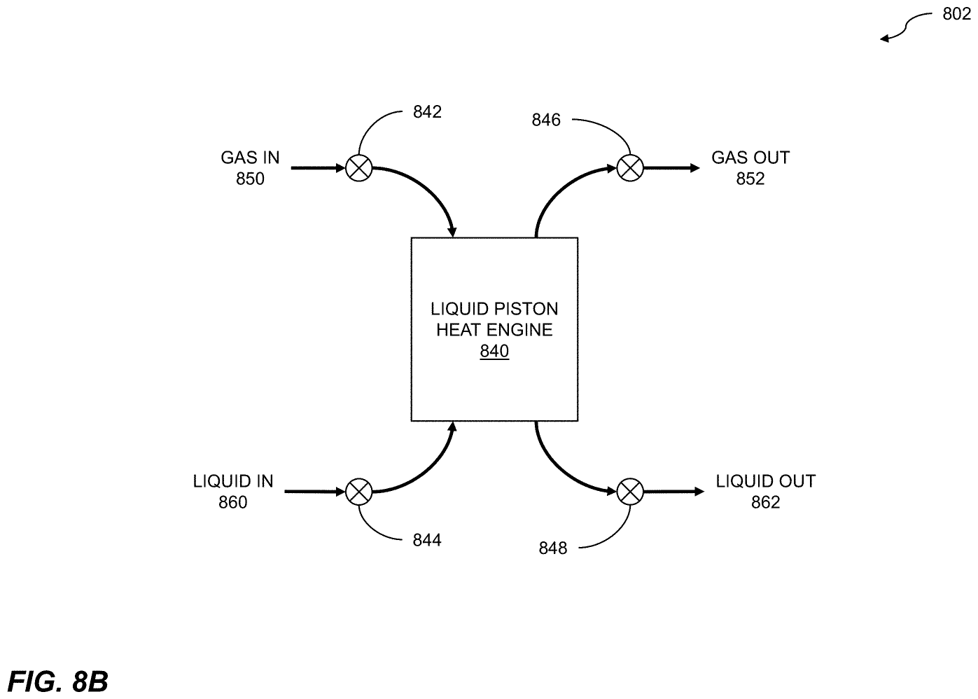

FIG. 8A illustrates a liquid piston heat engine (LPHE) to pressurize a liquid. The liquid piston heat engine can include a software-defined LPHE. In embodiments, the LPHE can include a water piston heat engine (WPHE), where the liquid comprises one or more types of water, such as fresh water, well water, sea water, recovery water, etc. The software-defined LPHE can use code to configure the software-defined functions, to control energy storage and recovery, and so on. The LPHE can include an energy management system that can be operated by an energy management control system. The energy management control system can be software-defined. The energy management control system can add or remove energy generation subsystems or energy storage subsystems as needed. The LPHE can be a component of a software-define mechanical machine. The liquid piston heat engine is based on control of software-defined mechanical machines using a description language. A hardware design is obtained for a mechanical system comprising a plurality of components that comprises a liquid piston heat engine. Couplings are described between the plurality of components. A plurality of layers is defined for the mechanical system. The mechanical system is implemented that comprises the liquid piston heat engine across the plurality of layers based on the couplings between the plurality of components. A liquid piston heat engine (LPHE) 810 can use a liquid to compress a gas or a gas to pressurize a liquid. A LPHE that uses a gas to pressurize a liquid is shown 800. A low-pressure liquid 820 such as water, liquid air, liquid nitrogen, and so on, can be provided to the LPHE. A high-pressure gas 830, where the gas can include air, nitrogen, etc., can also be provided to the LPHE. The high-pressure gas can be used to pressurize the liquid, where the pressurizing the liquid can be accomplished in a pressure vessel associated with the LPHE. The pressurized liquid 822 is available at an output of the LPHE. The pressurizing gas can exit the LPHE as a low-pressure gas 832.

FIG. 8B illustrates a logical model of a liquid piston heat engine 802. A logical model can be created, where the logical model can be associated with a software-defined machine. The software-defined machine, or SDM, can be controlled using a description language. A hardware design is obtained for a mechanical system comprising a plurality of components that comprises a liquid piston heat engine. Couplings are described between the plurality of components. A defining a plurality of layers is defined for the mechanical system. The mechanical system is implemented that comprises the liquid piston heat engine across the plurality of layers based on the couplings between the plurality of components. The logical model can use the description language to describe various components. In the example shown, the components can include a liquid piston heat engine 840 and valves such as 842, 844, 846, and 848. The valves can include smart valves. The logical model can further include inputs and outputs such as Gas In 850, Gas Out 852, Liquid In 860, and Liquid Out 862. The logical model can describe how the liquid can be used to compress the gas, the gas can be used to pressurize the liquid, etc. The software-defined machine uses a ruleset. The ruleset can include a system state table, a timing table, an event table, and a valve table. The software-define machine ruleset can further include a software-defined machine state table. The state table can include states such as breathe, compress, egress, drain, etc. The timing table can include start times and end times. The start time and end time pairs can be associated with state vector entries such as a start time and an end time pair for a breathe state. The event table can include events such as energy available for storage, power load spikes, component outages, and the like. The state machine can be based on code written in the description language to control the software-defined machine.

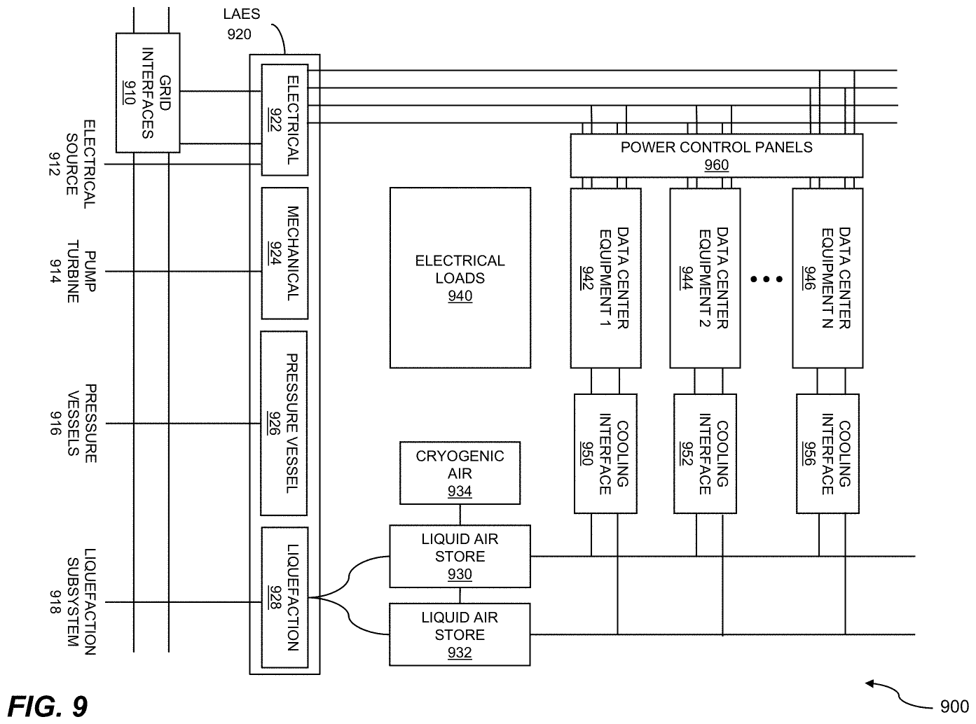

FIG. 9 shows example power distribution. Power can be generated using a software-defined mechanical machine. The software-defined mechanical machine can be controlled using a description language. The power that is distributed can include electrical power such as grid power, power recovered from storage, and so on. Power distribution can be accomplished using control and configuration of software-defined machines. A hardware design is obtained for a mechanical system comprising a plurality of components that comprises a liquid piston heat engine. Couplings are described between the plurality of components. A plurality of layers is defined for the mechanical system. The mechanical system is implemented that comprises the liquid piston heat engine across the plurality of layers based on the couplings between the plurality of components.

Example power distribution 900 can include one or more grid interfaces 910. Grid interfaces can include interfaces to power, where the power can include commercially generated “grid” power, renewable power, locally generated power or “microgrid” power, and so on. Other sources of power in addition to those coupled through the one or more grid interfaces can be included. The energy sources can include electrical sources 912. The electrical sources can include diesel-generator (DG) sets, uninterruptable power supplies (UPSs), batteries, supercapacitors, and so on. The energy sources can include pump-turbine sources 914. A pump-turbine can pump a gas or a liquid, or the pump-turbine can use a gas or a liquid to generate electrical energy. The energy sources can include pressure vessel sources 916. The pressure vessel sources can provide a compressed gas, a pressurized liquid, etc. The energy sources can include a liquefaction subsystem source 918. The liquefaction source can be based on a liquefied gas such as liquefied air. The liquefaction source can be coupled to one or more liquid air stores such as liquid air store 930 and liquid air store 932. The one or more liquid air stores can be further coupled to cryogenic air 934, where the cryogenic air can be used to maintain the liquid air in the one or more liquid air stores.

The power provided via the grid interfaces and energy provided from the electrical, pump-turbine, pressure vessel, or liquefaction sources can be provided to liquid air energy storage (LAES) 920. The LAES can energy storage and recovery components. The storage and recovery components can include electrical components 922, mechanical components 924, pressure vessels 926, and liquefaction components 928. The mechanical components, pressure vessels, and liquefaction components can be used to convert their stored energy to electrical energy. The LAES can provide power to electrical loads 940. The electrical loads can include electrical equipment such computing, storage, and communications equipment; heating, cooling and ventilation (HVAC) equipment; power distribution equipment; and the like. The electrical loads can include datacenter equipment located in datacenter or IT racks such as datacenter equipment 1 942, datacenter equipment 2 944, data center equipment N 946, etc. The liquid air within the one or more liquid air stores can be used to provide cooling to equipment within datacenter racks. The liquid air cooling can be provided using one or more cooling interfaces such as cooling interface 950, cooling interface 952, cooling interface 956, and so on. A cooling interface can provide one or more “cooling circuits” within a datacenter equipment rack. Each datacenter equipment rack is coupled to electrical sources using one or more power control panels 960. The power control panels can include switches, smart switches, etc.

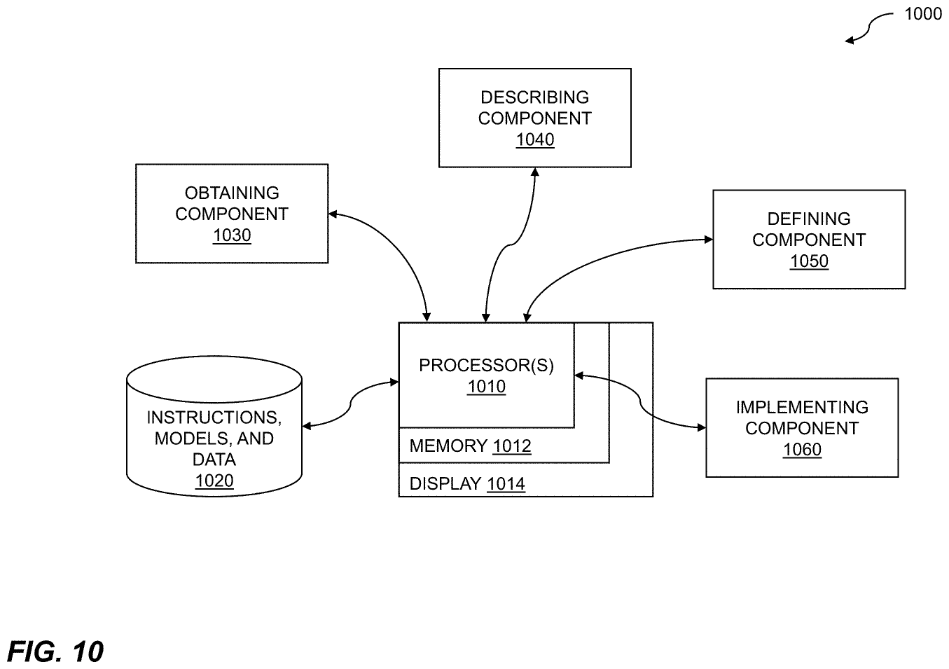

FIG. 10 is a system diagram for control and configuration of software-defined machines. Energy management is based on hardware description, where the hardware description includes software-defined machines. The software-defined mechanical machines enable liquid-based energy transfer. A hardware design is obtained for a mechanical system that includes a plurality of components that includes a liquid piston heat engine (LPHE). Couplings are described between the plurality of components. A plurality of layers is defined for the mechanical system. The layers within the plurality of layers can correspond to levels of hierarchy within the software-defined mechanical system. The mechanical system is implemented that comprises the liquid piston heat engine across the plurality of layers based on the couplings between the plurality of components. The software-defined machine can describe utilizing a liquid to compress a gas, utilizing a gas to pressurize a liquid, and so on. The compressing the gas and the pressurizing the liquid can be accomplished using the liquid piston heat engine. Pumping of a liquid into a high-pressure vessel can be controlled to accomplish compressing a gas where the compressing can produce heat. Liquid can be sprayed into the high-pressure vessel to cool the gas. Heat exchange can be performed to cool the liquid before spraying the liquid into the high-pressure vessel. The compressed gas can be stored in a storage reservoir such as an underground cavern or aquifer. The compressed gas can be extracted from the storage reservoir to drive a turbine to recover stored energy. The extracting gas from the storage reservoir can be accomplished using a second high-pressure vessel. The extracted gas can push a column of liquid within the second high-pressure vessel. The column of liquid within the second high-pressure vessel can drive the turbine to recover the stored energy. The system can be controlled to enable isothermal operation of one or high-pressure vessels. Isothermal operation can have an adiabaticity of substantially zero percent. The compression, extraction, energy recovery, and so on, are controlled by software-defined mechanical machines.

The system 1000 can include one or more processors 1010 and a memory 1012 which stores instructions. The memory 1012 is coupled to the one or more processors 1010, wherein the one or more processors 1010 can execute instructions stored in the memory 1012. The memory 1012 can be used for storing instructions; for storing databases of energy subsystems, modules, or peers for system support; for storing hardware designs based on description languages; and the like. Information regarding hardware descriptions for controlling software-defined mechanical machines can be shown on a display 1014 connected to the one or more processors 1010. The display can comprise a television monitor, a projector, a computer monitor (including a laptop screen, a tablet screen, a netbook screen, and the like), a smartphone display, a mobile device, or another electronic display. The system 1000 includes instructions, models, and data 1020. The data can include information on energy sources, energy conversion requirements, metadata about energy, and the like. In embodiments, the instructions, models, and data 1020 are stored in a networked database, where the networked database can be a local database, a remote database, a distributed database, and so on. The instructions, models, and data 1020 can include description language instructions for control of software-defined machines. The instructions can further include instructions for obtaining access to one or more high-pressure vessels. The instructions, models, and data can further include operating data obtained from a plurality of fluid-based local energy transfer distribution networks, one or more operating goals for the plurality of fluid-based local energy transfer distribution networks, instructions for analyzing operating data, instructions for controlling the operation of energy storage and generation assemblies, etc. The fluid-based energy storage and generation assemblies can include a pump running at an optimum performance-pressure point. An optimum performance-pressure point can be determined based on the design of the energy storage and generation assembly, on the past operation of the assembly, etc. Further embodiments include converting the pump optimum performance-pressure point pressure to a required pressure within the fluid-based local energy transfer distribution system using a pressure transformer amplifier.

The system 1000 includes an obtaining component 1030. The obtaining component 1030 can obtain a hardware design for a mechanical system comprising a plurality of components that comprises a liquid piston heat engine. In embodiments, the liquid piston heat engine comprises a water piston heat engine (WPHE). The mechanical system can include a software-defined machine. The software-defined machine can include a fluid-based local energy generation, storage, and transfer distribution system. The fluid-based system can compress a gas, pressurize a liquid, and so on. The fluid-based system can include a high-pressure vessel, a pump-turbine, valves, and so on. The fluid-based system can be based on a homogeneous fluid. The homogeneous fluid can include more than one phase such as a homogeneous fluid in liquid and gaseous phases. In embodiments, the software-defined machine can describe utilizing a liquid to compress a gas. The pressurizing the gas can include liquefying the gas. In other embodiments, the software-defined machine can describe utilizing a gas to pressurize a liquid. The pressurized liquid can be used to store energy such as excess energy from renewable sources. The pressurized liquid can be used to recover stored energy by spinning a turbine. The fluid-based system can be based more than one fluid. In embodiments, the fluid-based system can include at least two heterogeneous fluids. The liquid or liquids can include a variety of liquids such as liquid air, where the liquid air can be stored at a temperature less than −215° C.

In embodiments, the mechanical system can include energy storage. The energy storage can be based storing electrical energy, mechanical energy, chemical energy, thermal energy, kinetic energy. The energy can be stored as a compressed gas or pressurized liquid. In other embodiments, the mechanical system can further include energy generation. The energy generation can include electrical energy generation based on spinning a turbine, pump-turbine, etc. In embodiments, the hardware design can include a plurality of constraints for the mechanical system or components. The constraints can be based on cost, a contractual agreement, a service level agreement, component capabilities, and the like. In other embodiments, the hardware design can include a plurality of goals for the mechanical system. The goals can include generation cost, average load, peak load, seasonal load, etc.

The system 1000 includes a describing component 1040. The describing component 1040 can describe couplings between the plurality of components. The components, which can include one or more of turbines, pumps, pressure vessels, valves, smart valves, energy sources, energy generators, etc., can comprise components of a software-defined mechanical machine. The couplings can be configured, managed, controlled, and so on, using a hardware description language. The couplings can describe how the various components are configured; how the components can receive, store, recover, or transfer energy; and the like. The system 1000 includes a defining component 1050. The defining component can define a plurality of layers for the mechanical system. The layers can include a design hierarchy of the software-defined mechanical machine. In embodiments, the plurality of layers can provide progressive levels of abstraction for the mechanical system. An abstraction level “abstracts” detained machine complexity into a form that can be more easily understood by humans. In a design example, a stepper motor can be used to control a valve within a smart valve. Rather than needing to provide the stepper motor with a number of steps required to open a valve by an amount, the user may describe that the valve should be opened by 15 percent or that the valve should enable a certain flow rate. In embodiments, the plurality of layers can aggregate further components at higher levels of abstraction. The aggregation can include forming a submodule, module, subassembly, assembly, and so on from a set of components.

The system 1000 includes an implementing component 1060. The implementing component 1060 can implement the mechanical system that comprises the liquid piston heat engine across the plurality of layers based on the couplings between the plurality of components. The implementing the mechanical system can include generating description language code to control a software-defined mechanical machine. In embodiments, the implementing can include outputting a file including a hardware description language. The hardware description language can include a general-purpose language such as C, C++, or Python, or a language designed for power management and control. Discussed throughout, the hardware description language can describe a software-defined machine. The implementing can describe energy storage, energy recovery, energy conversion or generation, and the like. In embodiments, the software-defined machine can describe utilizing a liquid to compress a gas. The gas can include air, nitrogen, or other suitable gas. In other embodiments, the software-defined machine can describe utilizing a gas to pressurize a liquid. The liquid can include water, seawater, and so on. The liquid can include a liquefied gas such as liquid air, liquid nitrogen, FreonTM, and the like. In embodiments, the implementing can include matching needed component specifications with available components. Since the design that is implemented can be dynamic, the design can be updated based on changes to energy sources, storage availability, energy generation requirements, etc. The software-defined machine can be implemented by matching design needs or goals to component specification, reserving available energy system components, and the like. The implementing can include detailed energy system control information. In embodiments, the implementing can include providing valve open times, redundancy definitions, or a design envelope. The valve open times can be based on energy needs, valve capabilities, etc. The redundancy definitions can include redundancy such as N+1, 2N, and the like. The redundancy definitions can include safety margins. In other embodiments, the design envelope can include a maximum power generation capability or a maximum desalination capability.

The system 1000 can include a computer system for hardware description comprising: a memory which stores instructions; one or more processors coupled to the memory wherein the one or more processors, when executing the instructions which are stored, are configured to: obtain a hardware design for a mechanical system comprising a plurality of components that comprises a liquid piston heat engine; describe couplings between the plurality of components; define a plurality of layers for the mechanical system; and implement the mechanical system that comprises the liquid piston heat engine across the plurality of layers based on the couplings between the plurality of components. Disclosed embodiments include a computer program product embodied in a non-transitory computer readable medium for hardware description, the computer program product comprising code which causes one or more processors to perform operations of: obtaining a hardware design for a mechanical system comprising a plurality of components that comprises a liquid piston heat engine; describing couplings between the plurality of components; defining a plurality of layers for the mechanical system; and implementing the mechanical system that comprises the liquid piston heat engine across the plurality of layers based on the couplings between the plurality of components.

Each of the above methods may be executed on one or more processors on one or more computer systems. Embodiments may include various forms of distributed computing, client/server computing, and cloud-based computing. Further, it will be understood that the depicted steps or boxes contained in this disclosure's flow charts are solely illustrative and explanatory. The steps may be modified, omitted, repeated, or re-ordered without departing from the scope of this disclosure. Further, each step may contain one or more sub-steps. While the foregoing drawings and description set forth functional aspects of the disclosed systems, no particular implementation or arrangement of software and/or hardware should be inferred from these descriptions unless explicitly stated or otherwise clear from the context. All such arrangements of software and/or hardware are intended to fall within the scope of this disclosure.

The block diagrams and flowchart illustrations depict methods, apparatus, systems, and computer program products. The elements and combinations of elements in the block diagrams and flow diagrams, show functions, steps, or groups of steps of the methods, apparatus, systems, computer program products and/or computer-implemented methods. Any and all such functions—generally referred to herein as a “circuit,” “module,” or “system”—may be implemented by computer program instructions, by special-purpose hardware-based computer systems, by combinations of special purpose hardware and computer instructions, by combinations of general-purpose hardware and computer instructions, and so on.

A programmable apparatus which executes any of the above-mentioned computer program products or computer-implemented methods may include one or more microprocessors, microcontrollers, embedded microcontrollers, programmable digital signal processors, programmable devices, programmable gate arrays, programmable array logic, memory devices, application specific integrated circuits, or the like. Each may be suitably employed or configured to process computer program instructions, execute computer logic, store computer data, and so on.

It will be understood that a computer may include a computer program product from a computer-readable storage medium and that this medium may be internal or external, removable and replaceable, or fixed. In addition, a computer may include a Basic Input/Output System (BIOS), firmware, an operating system, a database, or the like that may include, interface with, or support the software and hardware described herein.

Embodiments of the present invention are limited to neither conventional computer applications nor the programmable apparatus that run them. To illustrate: the embodiments of the presently claimed invention could include an optical computer, quantum computer, analog computer, or the like. A computer program may be loaded onto a computer to produce a particular machine that may perform any and all of the depicted functions. This particular machine provides a means for carrying out any and all of the depicted functions.

Any combination of one or more computer readable media may be utilized including but not limited to: a non-transitory computer readable medium for storage; an electronic, magnetic, optical, electromagnetic, infrared, or semiconductor computer readable storage medium or any suitable combination of the foregoing; a portable computer diskette; a hard disk; a random access memory (RAM); a read-only memory (ROM), an erasable programmable read-only memory (EPROM, Flash, MRAM, FeRAM, or phase change memory); an optical fiber; a portable compact disc; an optical storage device; a magnetic storage device; or any suitable combination of the foregoing. In the context of this document, a computer readable storage medium may be any tangible medium that can contain or store a program for use by or in connection with an instruction execution system, apparatus, or device.

It will be appreciated that computer program instructions may include computer executable code. A variety of languages for expressing computer program instructions may include without limitation C, C++, Java, JavaScript™, ActionScrip™, assembly language, Lisp, Perl, Tcl, Python, Ruby, hardware description languages, database programming languages, functional programming languages, imperative programming languages, and so on. In embodiments, computer program instructions may be stored, compiled, or interpreted to run on a computer, a programmable data processing apparatus, a heterogeneous combination of processors or processor architectures, and so on. Without limitation, embodiments of the present invention may take the form of web-based computer software, which includes client/server software, software-as-a-service, peer-to-peer software, or the like.

In embodiments, a computer may enable execution of computer program instructions including multiple programs or threads. The multiple programs or threads may be processed approximately simultaneously to enhance utilization of the processor and to facilitate substantially simultaneous functions. By way of implementation, any and all methods, program codes, program instructions, and the like described herein may be implemented in one or more threads which may in turn spawn other threads, which may themselves have priorities associated with them. In some embodiments, a computer may process these threads based on priority or other order.

Unless explicitly stated or otherwise clear from the context, the verbs “execute” and “process” may be used interchangeably to indicate execute, process, interpret, compile, assemble, link, load, or a combination of the foregoing. Therefore, embodiments that execute or process computer program instructions, computer-executable code, or the like may act upon the instructions or code in any and all of the ways described. Further, the method steps shown are intended to include any suitable method of causing one or more parties or entities to perform the steps. The parties performing a step, or portion of a step, need not be located within a particular geographic location or country boundary. For instance, if an entity located within the United States causes a method step, or portion thereof, to be performed outside of the United States then the method is considered to be performed in the United States by virtue of the causal entity.

While the invention has been disclosed in connection with preferred embodiments shown and described in detail, various modifications and improvements thereon will become apparent to those skilled in the art. Accordingly, the foregoing examples should not limit the spirit and scope of the present invention; rather it should be understood in the broadest sense allowable by law.

What is claimed is:

1. A computer-implemented method for hardware control comprising:
obtaining a hardware design for a mechanical system comprising a plurality of components that comprises a liquid piston heat engine;
describing couplings between the plurality of components;
defining a plurality of layers for the mechanical system; and
implementing the mechanical system that comprises the liquid piston heat engine across the plurality of layers based on the couplings between the plurality of components.

2. The method of claim 1 wherein the couplings are described using connectivity maps.

3. The method of claim 1 wherein the implementing of the mechanical system is based on construction rules.

4. The method of claim 1 wherein the mechanical system implements a reverse osmosis desalination system.

5. The method of claim 1 wherein an application programming interface (API) is used to communicate information on the plurality of layers for the mechanical system.

6. The method of claim 5 wherein the plurality of layers provides progressive levels of abstraction for the mechanical system.

7. The method of claim 6 wherein the plurality of layers aggregates further components at higher levels of abstraction.

8. The method of claim 5 wherein the API communicates information on duration or schedule of energy generation or storage.

9. The method of claim 1 wherein the describing the couplings and the defining the plurality of layers is accomplished using a hardware description language.

10. The method of claim 9 wherein the hardware description language comprises an algebraic description of control operations.

11-14. (canceled)

15. The method of claim 1 wherein the implementing comprises outputting a file including a hardware description language.

16. The method of claim 15 wherein the hardware description language describes a software-defined machine.

17. The method of claim 16 wherein the software-defined machine describes utilizing a liquid to compress a gas.

18. The method of claim 16 wherein the software-defined machine describes utilizing a gas to pressurize a liquid.

19. The method of claim 1 wherein liquefaction is accomplished for a gas within the liquid piston heat engine.

20. The method of claim 1 wherein the mechanical system includes energy storage.

21. The method of claim 20 wherein the mechanical system further includes energy generation.

22. The method of claim 1 wherein the hardware design comprises a plurality of constraints for the mechanical system or components.

23. The method of claim 1 wherein the hardware design comprises a plurality of goals for the mechanical system.

24. The method of claim 1 wherein the components comprise pressure vessels, valves, turbines, or pumps.

25. (canceled)

26. The method of claim 1 wherein the implementing includes providing valve open times.

27. The method of claim 1 wherein the implementing includes redundancy definitions.

28. (canceled)

29. The method of claim 1 wherein the implementing includes design envelope parameters.

30. The method of claim 29 wherein the design envelope parameters include a maximum power generation capability or a maximum desalination capability.

31. A computer program product embodied in a non-transitory computer readable medium for hardware control, the computer program product comprising code which causes one or more processors to perform operations of:
obtaining a hardware design for a mechanical system comprising a plurality of components that comprises a liquid piston heat engine;
describing couplings between the plurality of components;
defining a plurality of layers for the mechanical system; and
implementing the mechanical system that comprises the liquid piston heat engine across the plurality of layers based on the couplings between the plurality of components.

32. A system for hardware control comprising:
a memory which stores instructions;
one or more processors coupled to the memory wherein the one or more processors, when executing the instructions which are stored, are configured to:
obtain a hardware design for a mechanical system comprising a plurality of components that comprises a liquid piston heat engine;
describe couplings between the plurality of components;
define a plurality of layers for the mechanical system; and
implement the mechanical system that comprises the liquid piston heat engine across the plurality of layers based on the couplings between the plurality of components.
